(19) United States
(12) Patent Application Publication
(10) Pub. No.: US 2022/0320097 A1
(43) Pub. Date: Oct. 6, 2022

(54) MEMORY-ELEMENT-INCLUDING SEMICONDUCTOR DEVICE

(71) Applicant: Unisantis Electronics Singapore Pte. Ltd., Singapore (SG)

(72) Inventors: Nozomu HARADA, Tokyo (JP); Koji SAKUI, Tokyo (JP)

(21) Appl. No.: 17/706,880

(22) Filed: Mar. 29, 2022

(30) Foreign Application Priority Data
Mar. 30, 2021 (JP) PCT/JP2021/013535

(51) Int. Cl. H01L 27/108

(52) U.S. Cl. CPC H01L 27/10802

(57) ABSTRACT

In a dynamic flash memory cell including a HfO₂ layer and a TiN layer surrounding a lower portion of a Si pillar standing on a P-layer substrate, a HfO₂ layer and a TiN layer surrounding an upper portion of the Si pillar, and N⁺ layers connecting to a bottom portion and a top portion of the Si pillar, and a Fin transistor including a SiO₂ layer surrounding a lower portion of a Si pillar standing also on the P-layer substrate, a HfO₂ layer and a TiN layer surrounding an upper portion of the Si pillar, and N⁺ layers connecting to both side surfaces of the upper portion of the Si pillar, the bottom portion positions of the Si pillar and the Si pillar are both at Position A, and the bottom portions of an SGT transistor unit constituted by, in the upper portion of the Si pillar, the HfO₂ layer and the TiN layer and a Fin transistor unit constituted by, in the upper portion of the Si pillar, the HfO₂ layer and the TiN layer are both at Position B.

### CROSS-REFERENCE TO RELATED APPLICATIONS

This application claims priority claims priority under 35 U.S.C. § 119(a) to PCT/JP2021/013535 filed on Mar. 30, 2021, the entire content of which is incorporated herein by reference.

### TECHNICAL FIELD

The present invention relates to a memory-element-including semiconductor device.

### BACKGROUND ART

In recent years, in development of the LSI (Large Scale Integration) technology, there has been a demand for memory-element-including semiconductor devices having a higher degree of integration and higher performance.

In the ordinary planar MOS transistor, the channel extends, along the upper surface of the semiconductor substrate, in the horizontal direction. By contrast, the channel of the SGT extends in a direction perpendicular to the upper surface of the semiconductor substrate (refer to, for example, Patent Literature 1 and Non Patent Literature 1). For this reason, the SGT enables, compared with the planar MOS transistor, an increase in the density of the semiconductor device. Use of this SGT as a select transistor enables a higher degree of integration in, for example, a DRAM (Dynamic Random Access Memory, refer to, for example, Non Patent Literature 2) to which a capacitor is connected, a PCM (Phase Change Memory, refer to, for example, Non Patent Literature 3) to which a resistance change element is connected, an RRAM (Resistive Random Access Memory, refer to, for example, Non Patent Literature 4), and an MRAM (Magneto-resistive Random Access Memory, refer to, for example, Non Patent Literature 5) in which a current is used to change the orientation of the magnetic spin to change the resistance. In addition, there is a capacitor-less DRAM memory cell constituted by a single MOS transistor (refer to Non Patent Literature 6), for example. The present application relates to a semiconductor device including a dynamic flash memory that does not include resistance change elements or capacitors and can be constituted by a MOS transistor alone.

For the above-described capacitor-less DRAM memory cell constituted by a single MOS transistor, FIGS. 7A-7D illustrate the write operation, FIGS. 8A-8B illustrate a problem in the operation, and FIGS. 9A-9C illustrate the read operation (refer to Non Patent Literatures 6 to 10).

FIGS. 7A-7D illustrate the write operation of the DRAM memory cell. FIG. 7A illustrates the “1” write state. This memory cell is formed on an SOI substrate 101, and is constituted by a source N⁺ layer 103 (hereafter, semiconductor regions containing donor impurities at high concentrations will be referred to as “N⁺ layers”) to which a source line SL is connected, a drain N⁺ layer 104 to which a bit line BL is connected, a gate conductive layer 105 to which a word line WL is connected, and a floating body (Floating Body) 102 of a MOS transistor 110a; thus, the capacitor-less DRAM memory cell is constituted by the single MOS transistor 110a. Note that the floating body 102 is in contact with the immediately underlying layer, the SiO₂ layer 101 of the SOI substrate. In the memory cell constituted by the single MOS transistor 110a, in order to write “1”, the MOS transistor 110a is operated in the saturation region. Specifically, an electron channel 107 extending from the source N⁺ layer 103 has a pinch-off point 108 and does not reach the drain N⁺ layer 104 to which the bit line is connected. Thus, when the MOS transistor 110a is operated such that the bit line BL connected to the drain N⁺ layer 104 and the word line WL connected to the gate conductive layer 105 are set at high voltages, and the gate voltage is set at about ½ of the drain voltage, the electric field strength becomes maximum at the pinch-off point 108 near the drain N⁺ layer 104. As a result, accelerated electrons flowing from the source N⁺ layer 103 to the drain N⁺ layer 104 collide with the Si lattice, and the kinetic energy lost at this time causes generation of electron-hole pairs. Most of the generated electrons (not shown) reach the drain N⁺ layer 104. A very small portion of the electrons, very hot electrons jump over a gate oxide film 109, to reach the gate conductive layer 105. Holes 106 generated at the same time charge the floating body 102. In this case, the generated holes contribute, in the floating body 102 formed of P-type Si, as an increment of the majority carrier. When the floating body 102 is filled with the generated holes 106 and the voltage of the floating body 102 become higher than that of the source N⁺ layer 103 by Vb or more, holes further generated are discharged to the source N⁺ layer 103. Vb is the built-in voltage of the PN junction between the source N⁺ layer 103 and the P-layer floating body 102, and is about 0.7 V. FIG. 7B illustrates a state in which the floating body 102 is charged to saturation with the holes 106 generated.

Hereinafter, with reference to FIG. 7C, the “0” write operation of the memory cell 110 will be described. For the common select word line WL, there are randomly a memory cell 110a to which “1” is written and a memory cell 110b to which “0” is written. FIG. 7C illustrates a state of a rewrite from a “1” write state to a “0” write state. In order to write “0”, the voltage of the bit line BL is set to a negative bias and the PN junction between the drain N⁺ layer 104 and the P-layer floating body 102 is forward biased. As a result, the holes 106 generated in advance in the floating body 102 in the previous cycle flow to the drain N⁺ layer 104 connected to the bit line BL. Completion of the write operation provides two states of memory cells that are the memory cell 110a filled with the generated holes 106 (FIG. 7B) and the memory cell 110b from which the generated holes have been discharged (FIG. 7C). In the memory cell 110a filled with the holes 106, the floating body 102 has a higher potential than the floating body 102 not having generated holes. Thus, the threshold voltage of the memory cell 110a becomes lower than the threshold voltage of the memory cell 110b. This state is illustrated in FIG. 7D.

Hereinafter, a problem in the operation of the memory cell constituted by a single MOS transistor will be described with reference to FIGS. 8A-8B. As illustrated in FIG. 8A, the capacitance C_{FB} of the floating body 102 is the sum of the capacitance C_{WL} between the gate to which the word line is connected and the floating body 102, the junction capacitance C_{SL} of the PN junction between the source N⁺ layer 103 to which the source line is connected and the floating body 102, and the junction capacitance C_{BL} of the PN junction between the drain N⁺ layer 103 to which the bit line is connected and the floating body 102, and is expressed as follows.

C_{FB}=C_{WL}+C_{BL}+C_{SL} (1)

Thus, a change in the word line voltage V_{WL} at the time of writing affects the voltage of the floating body 102 serving as the storage node (contact point) of the memory cell. This state is illustrated in FIG. 8B. At the time of writing, an increase in the word line voltage V_{WL} from 0 V to V_{ProgWL} results in an increase in the voltage V_{FB} of the floating body 102 from the initial voltage V_{FB1} of the original word line voltage to V_{FB2} due to capacitive coupling with the word line. The voltage change amount ΔV_{FB} is expressed as follows:

ΔV_{FB}=V_{FB2}−V_{FB1}=C_{WL}/(C_{WL}+C_{BL}+C_{SL})×V_{ProqgWL} (2)

where

β=C_{WL}/(C_{WL}+C_{BL}+C_{SL}) (3)

is expressed and β is referred to as a coupling ratio. In such a memory cell, C_{WL} has a high contribution ratio and, for example, C_{WL}:C_{BL}:C_{SL}=8:1:1. In this case, β=0.8. When the word line changes, for example, from 5 V at the time of writing to 0 V at the end of writing, the capacitive coupling between the word line and the floating body 102 causes an amplitude noise as much as 5 V×β=4 V on the floating body 102. Thus, the potential difference margin is not sufficiently provided between the “1” potential and the “0” potential of the floating body at the time of writing, which is a problem.

FIGS. 9A-9C illustrates the read operation. FIG. 9A illustrates the “1” write state, and FIG. 9B illustrates the “0” write state. However, actually, even when “1” is written to write Vb in the floating body 102, returning of the word line to 0 V upon completion of writing brings the floating body 102 to a negative bias. When “0” is written, lowering to a further negative bias is caused, so that, at the time of writing, the potential difference margin between “1” and “0” cannot be made sufficiently large. This small operation margin is a major problem of the DRAM memory cell. In addition, formation of a peripheral circuit for driving the DRAM memory cell, on the same substrate, needs to be achieved.

There is a Twin-Transistor memory element in which, in an SOI (Silicon on Insulator) layer, two MOS transistors are used to form a single memory cell (refer to, for example, Patent Literatures 4 and 5). In such an element, an N⁺ layer separating the floating body channels of the two MOS transistors and serving as the source or the drain is formed in contact with an insulating layer. This N⁺ layer is in contact with the insulating layer to thereby provide electric isolation between the floating body channels of the two MOS transistors. The hole group serving as signal charges is stored in the floating body channel of one of the transistors. As described above, the voltage of the floating body channel in which holes are stored considerably varies due to application of a pulse voltage to the gate electrode of the adjacent MOS transistor, as expressed in Formula (2). Thus, as has been described with reference to FIG. 7A to FIG. 9C, the operation margin between “1” and “0” at the time of writing cannot be made sufficiently large (refer to, for example, Non Patent Literature 13 and FIGS. 8A-8B).

### CITATION LIST

### Patent Literature

[PTL 1] Japanese Unexamined Patent Application Publication No. 2-188966
[PTL 2] Japanese Unexamined Patent Application Publication No. 3-171768
[PTL 3] Japanese Patent No. 3957774
[PTL 4] US2008/0137394 A1
[PTL 5] US2003/0111681 A1

### Non Patent Literature

[NPL 1] Hiroshi Takato, Kazumasa Sunouchi, Naoko Okabe, Akihiro Nitayama, Katsuhiko Hieda, Fumio Horiguchi, and Fujio Masuoka: IEEE Transaction on Electron Devices, Vol. 38, No. 3, pp. 573-578 (1991)
[NPL 2] H. Chung, H. Kim, H. Kim, K. Kim, S. Kim, K. Dong, J. Kim, Y. C. Oh, Y. Hwang, H. Hong, G. Jin, and C. Chung: “4F2 DRAM Cell with Vertical Pillar Transistor (VPT),” 2011 Proceeding of the European Solid-State Device Research Conference, (2011)
[NPL 3] H. S. Philip Wong, S. Raoux, S. Kim, Jiale Liang, J. R. Reifenberg, B. Rajendran, M. Asheghi and K. E. Goodson: “Phase Change Memory,” Proceeding of IEEE, Vol. 98, No 12, December, pp. 2201-2227 (2010)
[NPL 4] T. Tsunoda, K. Kinoshita, H. Noshiro, Y. Yamazaki, T. Iizuka, Y. Ito, A. Takahashi, A. Okano, Y. Sato, T. Fukano, M. Aoki, and Y. Sugiyama: “Low Power and high Speed Switching of Ti-doped NiO ReRAM under the Unipolar Voltage Source of less than 3V,” IEDM (2007)
[NPL 5] W. Kang, L. Zhang, J. Klein, Y. Zhang, D. Ravelosona, and W. Zhao: “Reconfigurable Codesign of STT-MRAM Under Process Variations in Deeply Scaled Technology,” IEEE Transaction on Electron Devices, pp. 1-9 (2015)
[NPL 6] M. G. Ertosum, K. Lim, C. Park, J. Oh, P. Kirsch, and K. C. Saraswat: “Novel Capacitorless Single-Transistor Charge-Trap DRAM (1T CT DRAM) Utilizing Electron,” IEEE Electron Device Letter, Vol. 31, No. 5, pp. 405-407 (2010)
[NPL 7] J. Wan, L. Rojer, A. Zaslavsky, and S. Critoloveanu: “A Compact Capacitor-Less High-Speed DRAM Using Field Effect-Controlled Charge Regeneration,” Electron Device Letters, Vol. 35, No. 2, pp. 179-181 (2012)
[NPL 8] T. Ohsawa, K. Fujita, T. Higashi, Y. Iwata, T. Kajiyama, Y. Asao, and K. Sunouchi: “Memory design using a one-transistor gain cell on SOI,” IEEE JSSC, vol. 37, No. 11, pp 1510-1522 (2002).
[NPL 9] T. Shino, N. Kusunoki, T. Higashi, T. Ohsawa, K. Fujita, K. Hatsuda, N. Ikumi, F. Matsuoka, Y. Kajitani, R. Fukuda, Y. Watanabe, Y. Minami, A. Sakamoto, J. Nishimura, H. Nakajima, M. Morikado, K. Inoh, T. Hamamoto, A. Nitayama: “Floating Body RAM Technology and its Scalability to 32 nm Node and Beyond,” IEEE IEDM (2006).
[NPL 10] E. Yoshida: “A Capacitorless 1T-DRAM Technology Using Gate-Induced Drain-Leakage (GIDL) Current for Low-Power and High-Speed Embedded Memory,” IEEE IEDM (2006).
[NPL 11] E. Yoshida, and T. Tanaka: “A Capacitorless 1T-DRAM Technology Using Gate-Induced Drain-Leakage (GIDL) Current for Low-Power and High-Speed Embedded Memory,” IEEE Transactions on Electron Devices, Vol. 53, No. 4, pp. 692-697, April 2006.
[NPL 12] Asen Asenov, Binjie Cheng, XingshengWang, Andrew Robert Brown, Campbell Millar, Craig Alexander, Salvatore Maria Amoroso, Jente B. Kuang, and Sani R. Nassif, “Variability Aware Simulation Based Design-Technology Cooptimization (DTCO) Flow in 14 nm FinFET/SRAM Cooptimization, “IEEE Transaction on Electron Devices, Vol. 62, No. 6 (2015)
[NPL 13] F. Morishita, H. Noda, I. Hayashi, T. Gyohten, M. Oksmoto, T. Ipposhi, S. Maegawa, K. Dosaka, and K. Arimoto: “Capacitorless Twin-Transistor Random Access Memory (TTRAM) on SOI,” IEICE Trans. Electron., Vol. E90-c., No. 4 pp. 765-771 (2007)

### SUMMARY OF INVENTION

### Technical Problem

In an SGT-including memory device that is a capacitor-less single-transistor DRAM (gain cell), capacitive coupling between the word line and the floating SGT body is strong; at the time of reading or writing of data, a change in the potential of the word line is transmitted directly as noise to the SGT body, which has been problematic. This causes problems of erroneous reading or erroneous writing of storage data and makes it difficult to put the capacitor-less single-transistor DRAM (gain cell) into practical use. The above-described problems need to be addressed and, on the substrate of the memory cell, a peripheral circuit for driving the memory cell also needs to be formed at a high density and at low costs.

### Solution to Problem

In order to address such problems, the present invention provides a memory-element-including semiconductor device including a dynamic flash memory cell and a Fin transistor,

wherein the dynamic flash memory cell includes

a first semiconductor pillar disposed on a substrate so as to stand in a direction perpendicular to the substrate,

a first impurity layer connecting to a bottom portion of the first semiconductor pillar,

a second impurity layer disposed in a top portion of the first semiconductor pillar or disposed so as to connect to the top portion,

a first gate insulating layer surrounding a lower portion of the first semiconductor pillar and being in contact with the first impurity layer,

a second gate insulating layer being in contact with the first gate insulating layer and surrounding an upper portion of the first semiconductor pillar,

a first gate conductor layer surrounding a portion or entirety of the first gate insulating layer,

a second gate conductor layer surrounding the second gate insulating layer, and

a first insulating layer disposed between the first gate conductor layer and the second gate conductor layer,

the dynamic flash memory cell is configured to perform a memory write operation of controlling voltages applied to the first impurity layer, the second impurity layer, the first gate conductor layer, and the second gate conductor layer to perform an operation of causing, within the first semiconductor pillar, an impact ionization phenomenon due to a current flowing between the first impurity layer and the second impurity layer or a gate induced drain leakage current to generate an electron group and a hole group, an operation of discharging, of the generated electron group and hole group, the electron group from the first impurity layer or the second impurity layer, and causing a portion or entirety of the hole group to remain within the first semiconductor pillar, and a memory erase operation of removing, from one or both of the first impurity layer and the second impurity layer, the remaining hole group of the hole group,

the Fin transistor includes

a second semiconductor pillar disposed on the substrate so as to stand in a direction perpendicular to the substrate,

a second insulating layer surrounding a lower portion of the second semiconductor pillar,

a third impurity layer and a fourth impurity layer individually connecting to, above the second insulating layer, both side surfaces, in a longitudinal direction, of an upper portion of the second semiconductor pillar,

a third gate insulating layer surrounding the third impurity layer, the fourth impurity layer, and the second semiconductor pillar therebetween, and

a third gate conductor layer surrounding the third gate insulating layer, and

bottom portions of the first semiconductor pillar and the second semiconductor pillar are disposed at substantially the same position in the perpendicular direction (first invention).

In the first invention, in the perpendicular direction, a lower end of the second gate conductor layer and a lower end of the third gate conductor layer are substantially at the same position (second invention).

In the first invention, top portions of the first semiconductor pillar and the second semiconductor pillar are substantially at the same position in the perpendicular direction (third invention).

In the first invention, the second impurity layer, the third impurity layer, and the fourth impurity layer contain the same donor impurity atoms and are formed of the same semiconductor base material (fourth invention).

In the first invention, a wiring line connecting to the first impurity layer is a source line, a wiring line connecting to the second impurity layer is a bit line, a wiring line connected to one of the first gate conductor layer and the second gate conductor layer is a first driving control line, a wiring line connected to another of the first gate conductor layer and the second gate conductor layer is a word line, and voltages are applied to the source line, the bit line, the first driving control line, and the word line, to perform the memory erase operation and the memory write operation (fifth invention).

In the first invention, a first gate capacitance between the first gate conductor layer and the first semiconductor pillar is higher than a second gate capacitance between the second gate conductor layer and the first semiconductor pillar (sixth invention).

In the first invention, the first gate conductor layer is, in plan view, divided into two conductor layers so as to surround the first gate insulating layer (seventh invention).

### BRIEF DESCRIPTION OF DRAWINGS

FIG. 1 is a structural view of an SGT-including memory device according to a first embodiment.

FIGS. 2A, 2B and 2C are explanatory views of the erase operation mechanism of an SGT-including memory device according to a first embodiment.

FIGS. 3A, 3B and 3C are explanatory views of the write operation mechanism of an SGT-including memory device according to a first embodiment.

FIGS. 4AA, 4AB and 4AC are explanatory views of the read operation mechanism of an SGT-including memory device according to a first embodiment.

FIGS. 4BD, 4BE, 4BF and 4BG are explanatory views of the read operation mechanism of an SGT-including memory device according to a first embodiment.

FIGS. 5A, 5B, 5C, and 5D are explanatory views of the structures of a dynamic flash memory cell according to a first embodiment and a Fin transistor used as the driving circuit and the signal processing circuit for the dynamic flash memory cell.

FIGS. 6AA, 6AB, 6AC and 6AD are explanatory views of a production method according to a second embodiment in which a dynamic flash memory cell and a Fin transistor are formed on the same substrate.

FIGS. 6BA, 6BB, 6BC and 6BD are explanatory views of a production method according to a second embodiment in which a dynamic flash memory cell and a Fin transistor are formed on the same substrate.

FIGS. 6CA, 6CB, 6CC and 6CD are explanatory views of a production method according to a second embodiment in which a dynamic flash memory cell and a Fin transistor are formed on the same substrate.

FIGS. 6DA, 6DB, 6DC and 6DD are explanatory views of a production method according to a second embodiment in which a dynamic flash memory cell and a Fin transistor are formed on the same substrate.

FIGS. 6EA, 6EB, 6EC and 6ED are explanatory views of a production method according to a second embodiment in which a dynamic flash memory cell and a Fin transistor are formed on the same substrate.

FIGS. 6FA, 6FB, 6FC and 6FD are explanatory views of a production method according to a second embodiment in which a dynamic flash memory cell and a Fin transistor are formed on the same substrate.

FIGS. 6GA, 6GB, 6GC and 6GD are explanatory views of a production method according to a second embodiment in which a dynamic flash memory cell and a Fin transistor are formed on the same substrate.

FIGS. 6HA, 6HB, 6HC and 6HD are explanatory views of a production method according to a second embodiment in which a dynamic flash memory cell and a Fin transistor are formed on the same substrate.

FIGS. 6IA, 6IB, 6IC and 6ID are explanatory views of a production method according to a second embodiment in which a dynamic flash memory cell and a Fin transistor are formed on the same substrate.

FIGS. 6JA, 6JB, 6JC and 6JD are explanatory views of a production method according to a second embodiment in which a dynamic flash memory cell and a Fin transistor are formed on the same substrate.

FIGS. 6KA, 6KB, 6KB and 6KB are explanatory views of a production method according to a second embodiment in which a dynamic flash memory cell and a Fin transistor are formed on the same substrate.

FIGS. 7A, 7B, 7C and 7D are explanatory views of a problem in the operation of a related-art capacitor-less DRAM memory cell.

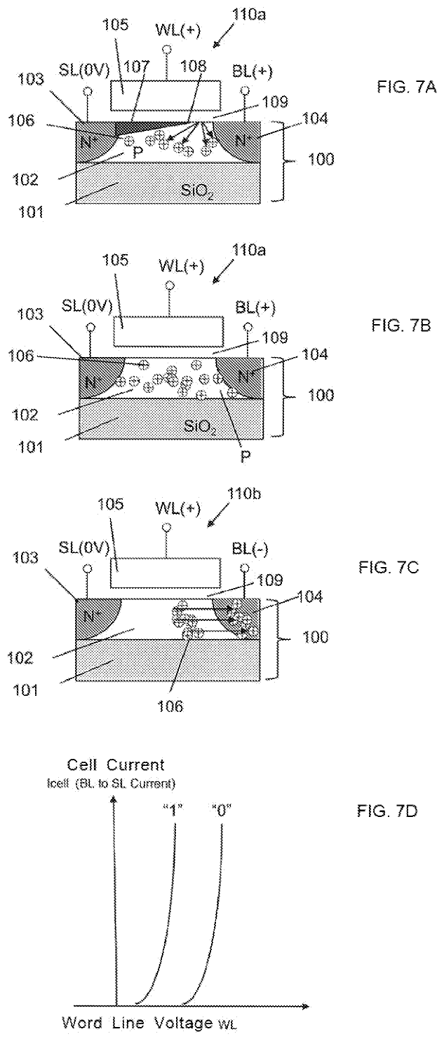

FIGS. 8A and 8B are explanatory views of a problem in the operation of a related-art capacitor-less DRAM memory cell.

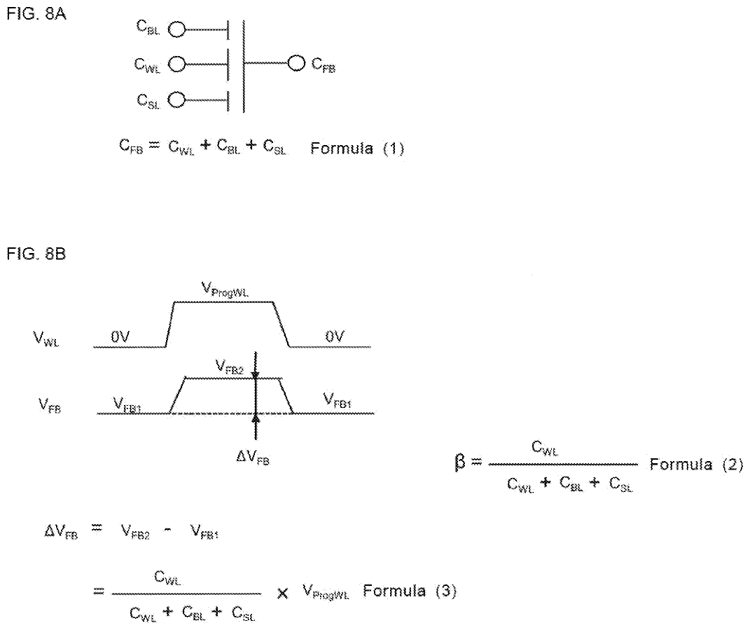

FIGS. 9A, 9B and 9C illustrate the read operation of a related-art capacitor-less DRAM memory cell.

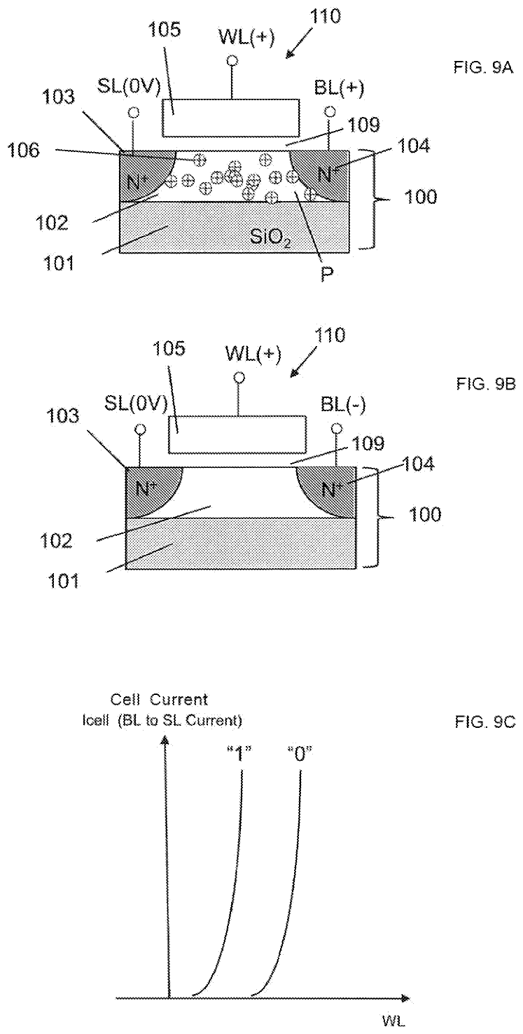

### DESCRIPTION OF EMBODIMENTS

Hereinafter, a memory device using a semiconductor element (hereafter, referred to as a dynamic flash memory) according to embodiments of the present invention will be described in terms of structures and operations with reference to drawings. In addition, such a dynamic flash memory cell and a Fin transistor for a driving circuit and a signal processing circuit connecting to the dynamic flash memory cell (refer to, for example, NPL 12) formed on the same substrate will be described in terms of structures and the production method of both with reference to drawings.

### First Embodiment

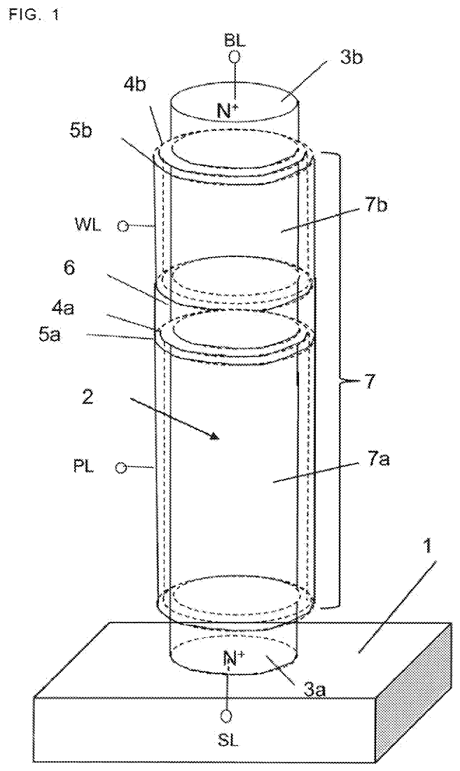

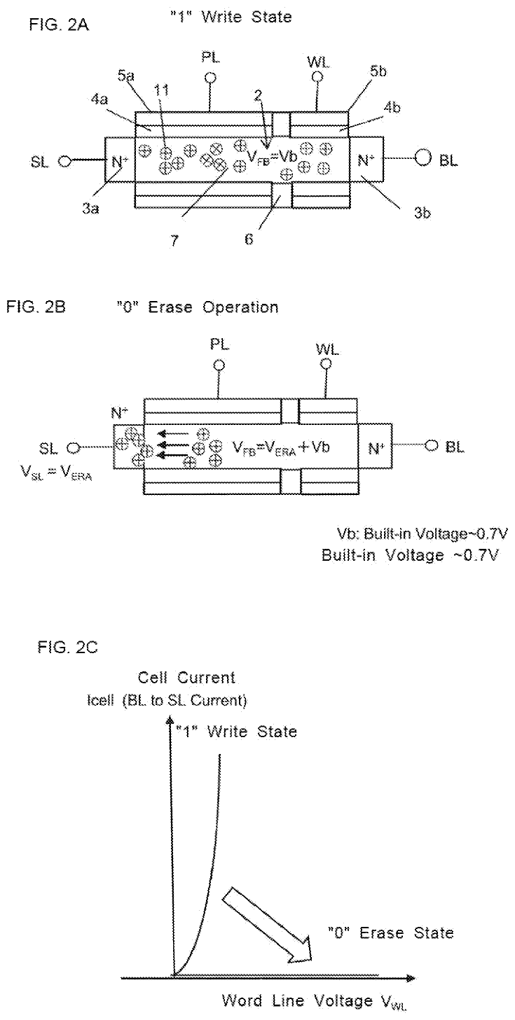

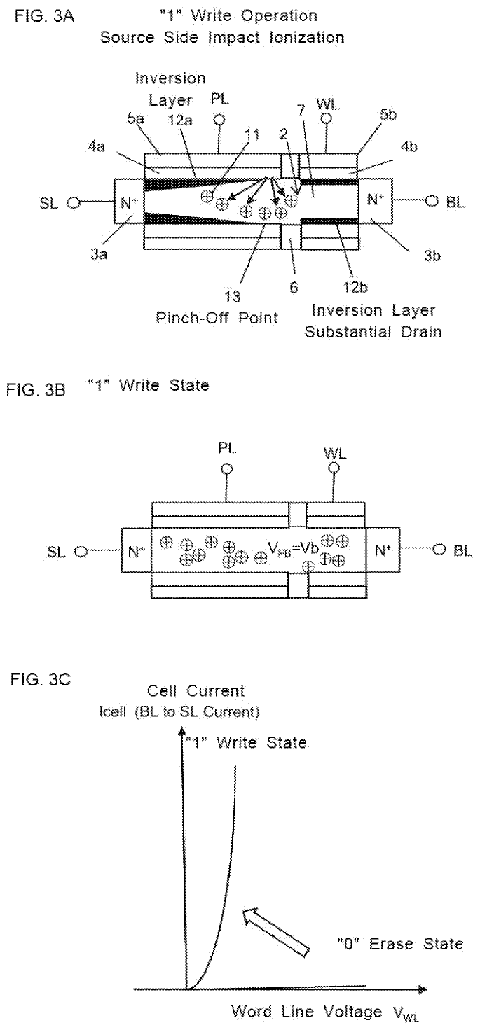

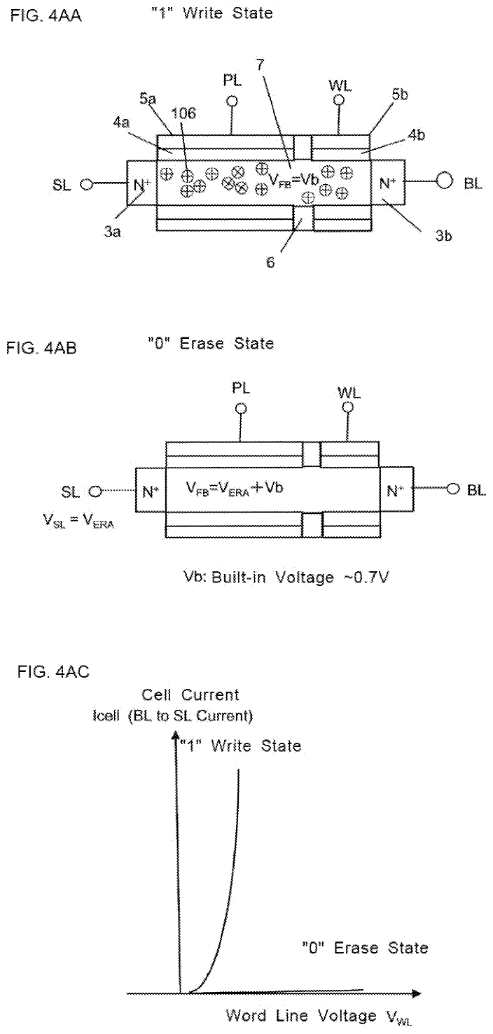

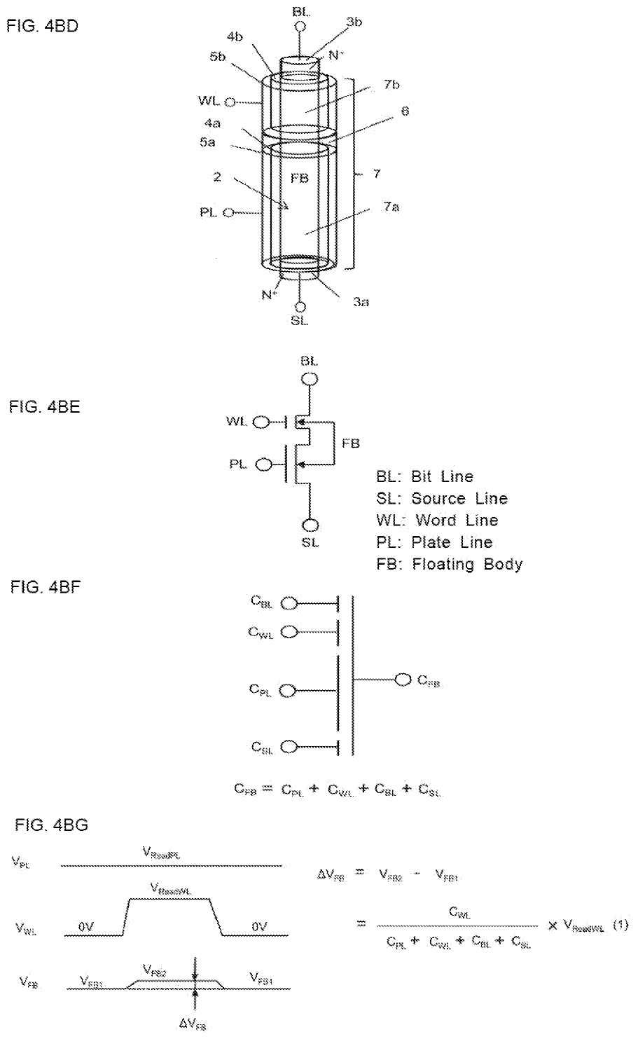

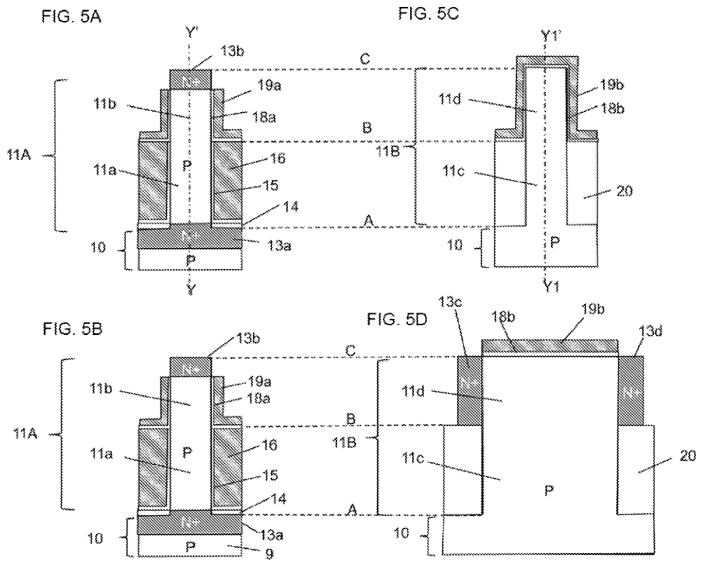

FIG. 1 to FIGS. 5A-5D will be used to describe a dynamic flash memory cell according to a first embodiment of the present invention in terms of structure and operation mechanisms. FIG. 1 will be used to describe the structure of the dynamic flash memory cell. Subsequently, FIGS. 2A-2C will be used to describe the data erase mechanism; FIGS. 3A-3C will be used to describe the data write mechanism; FIGS. 4AA-4BG will be used to describe the data write mechanism. FIGS. 5A-5D will be used to describe the structures of the memory cell of the dynamic flash memory, and the Fin transistor for driving the memory cell.

FIG. 1 illustrates the structure of a dynamic flash memory cell according to the first embodiment of the present invention. On a substrate 1 (serving as an example of “substrate” in CLAIMS), upwardly, a P-type or i-type (intrinsic type) conductivity type silicon pillar 2 (serving as an example of “first semiconductor pillar” in CLAIMS) (hereafter, silicon pillars will be referred to as “Si pillars”), an N⁺ layer 3a (serving as an example of “first impurity layer” in CLAIMS) connecting to the bottom portion of the Si pillar 2, and an N⁺ layer 3b (serving as an example of “second impurity layer” in CLAIMS) connecting to the top portion of the Si pillar 2 are formed. One of the N⁺ layer 3a and the N⁺ layer 3b serves as the source while the other serves as the drain. In the Si pillar 2, the region between the N⁺ layer 3a and the N⁺ layer 3b serves as a channel region 7. A first gate insulating layer 4a (serving as an example of “first gate insulating layer” in CLAIMS) surrounding the lower portion of the Si pillar 2, and a second gate insulating layer 4b (serving as an example of “second gate insulating layer” in CLAIMS) surrounding the upper portion of the Si pillar 2 are formed. These first gate insulating layer 4a and the second gate insulating layer 4b are respectively disposed in contact with or near the N⁺ layers 3a and 3b serving as the source and the drain. A first gate conductor layer 5a (serving as an example of “first gate conductor layer” in CLAIMS) surrounding the first gate insulating layer 4a, and a second gate conductor layer 5b (serving as an example of “second gate conductor layer” in CLAIMS) surrounding the second gate insulating layer 4b are individually formed. The first gate conductor layer 5a and the second gate conductor layer 5b are isolated from each other by an insulating layer 6 (serving as an example of “first insulating layer” in CLAIMS). The channel region 7 is constituted by a first channel region 7a surrounded by the first gate insulating layer 4a, and a second channel region 7b surrounded by the second gate insulating layer 4b. Thus, the N⁺ layers 3a and 3b serving as the source and the drain, the channel region 7, the first gate insulating layer 4a, the second gate insulating layer 4b, the first gate conductor layer 5a, and the second gate conductor layer 5b constitute a dynamic flash memory cell 9. The N⁺ layer 3a is connected to a source line SL (serving as an example of “source line” in CLAIMS); the N⁺ layer 3b is connected to a bit line BL (serving as an example of “bit line” in CLAIMS); the first gate conductor layer 5a is connected to a plate line PL (serving as an example of “first driving control line” in CLAIMS); the second gate conductor layer 5b is connected to a word line WL (serving as an example of “word line” in CLAIMS). Note that the substrate 1 is a base material layer having an upper surface connecting to the perpendicularly standing Si pillar 2 and spreading in the horizontal direction. Thus, in the perpendicular direction, of the N⁺ layer 13a, a portion below the surface of the substrate 1 is regarded as the substrate 1. This portion of the N⁺ layer 13a within the substrate 1 may spread in the horizontal direction. The substrate 1 may be formed as SOI (Silicon On Insulator) or a monolayer or a multilayer of Si or another semiconductor material. The substrate 1 may be a well layer constituted by a monolayer or a multilayer of N layers or P layers.

Referring to FIGS. 2A-2C, the erase operation mechanism will be described. The channel region 7 between the N⁺ layers 3a and 3b is electrically isolated from the substrate to serve as a floating body. FIG. 2A illustrates a state in which, prior to the erase operation, a hole group 11 generated by impact ionization in the previous cycle is stored in the channel region 7. As illustrated in FIG. 2B, at the time of the erase operation, the voltage of the bit line BL is set to a negative voltage V_{ERA}. V_{ERA} is, for example, −3 V. As a result, irrespective of the initial potential value of the channel region 7, the PN junction between the N⁺ layer 3a to which the source line SL is connected and which serves as the source and the channel region 7 is forward biased. As a result, the hole group 11 generated in the previous cycle by impact ionization and stored in the channel region 7 is drawn into the N⁺ layer 3a serving as the source region, and the potential V_{FB} of the channel region 7 becomes V_{FB}=V_{ERA}+Vb where Vb is the built-in voltage of the PN junction and is about 0.7 V. Thus, when V_{ERA}=−3 V, the potential of the channel region 7 becomes −2.3 V. This value corresponds to the potential state of the channel region 7 in an erase state. Thus, when the potential of the channel region 7 of the floating body becomes a negative voltage, the threshold voltage of the N channel MOS transistor of the dynamic flash memory cell 9 increases due to the substrate bias effect. This results in, as illustrated in FIG. 2C, an increase in the threshold voltage of the second gate conductor layer 5b to which the word line WL is connected. This erase state of the channel region 7 is assigned to logical storage data “0”. In data reading, the voltage applied to the first gate conductor layer 5a connecting to the plate line PL is set to be higher than the threshold voltage at the time of logical storage data “1” and to be lower than the threshold voltage at the time of logical storage data “0”, to thereby provide, as illustrated in FIG. 2C, a property in which, in reading of logical storage data “0”, in spite of setting the word line WL to a high voltage, no current flows. Note that the conditions of voltages applied to the bit line BL, the source line SL, the word line WL, and the plate line PL are an example for performing the erase operation; other operation conditions for performing the erase operation may be employed. For example, a voltage difference may be applied between the bit line BL and the source line SL to cause a current to flow in the channel region 7 and electron-hole recombination occurring at this time may be used to perform the erase operation.

FIGS. 3A-3C illustrate the write operation of the dynamic flash memory cell according to the first embodiment of the present invention. As illustrated in FIG. 3A, for example, 0 V is applied to the N⁺ layer 3a to which the source line SL is connected; for example, 3 V is applied to the N⁺ layer 3b to which the bit line BL is connected; for example, 2 V is applied to the first gate conductor layer 5a to which the plate line PL is connected; for example, 5 V is applied to the second gate conductor layer 5b to which the word line WL is connected. As a result, as illustrated in FIG. 3A, in the inner region relative to the first gate conductor layer 5a to which the plate line PL is connected, an inversion layer 12a is formed; the first N channel MOS transistor including the first gate conductor layer 5a is operated in the saturation region. This results in, in the inversion layer 12a in the inner region relative to the second gate conductor layer 5b to which the plate line PL is connected, the presence of a pinch-off point 13. On the other hand, a second N channel MOS transistor including the second gate conductor layer 12b to which the word line WL is connected is operated in the linear region. This results in, in the inner region relative to the second gate conductor layer 5b to which the word line WL is connected, without the presence of the pinch-off point, formation of an inversion layer 12b over the entire surface. The inversion layer 12b formed over the entire surface in the inner region relative to the second gate conductor layer 5b to which the word line WL is connected serves as substantially the drain of the second N channel MOS transistor including the second gate conductor layer 5b. As a result, the electric field becomes maximum in the boundary region of the channel region 7 between the first N channel MOS transistor including the first gate conductor layer 5a and the second N channel MOS transistor including the second gate conductor layer 5b that are connected in series and, in this region, an impact ionization phenomenon is caused. This region is a source-side region when viewed from the second N channel MOS transistor including the second gate conductor layer 5b to which the word line WL is connected, and hence this phenomenon will be referred to as a source-side impact ionization phenomenon. This source-side impact ionization phenomenon causes electrons to flow from the N⁺ layer 3a to which the source line SL is connected to the N⁺ layer 3b to which the bit line is connected. Accelerated electrons collide with lattice Si atoms, and the kinetic energy causes generation of electron-hole pairs. A portion of the generated electrons flows to the first gate conductor layer 5a and the second gate conductor layer 5b, but most of the generated electrons flow to the N⁺ layer 3b to which the bit line BL is connected. In writing of “1”, GIDL (Gate Induced Drain Leakage) current may be used to generate electron-hole pairs (refer to NPL 11), to cause the generated hole group to fill the floating body FB. Note that generation of electron-hole pairs due to the impact ionization phenomenon can also be caused at the boundary between the N⁺ layer 3a and the channel region 7 or the boundary between the N⁺ layer 3b and the channel region 7. The impact ionization phenomenon may be caused in a portion of or the entirety of the second channel region 7b.

As illustrated in FIG. 3B, the generated hole group 11 is the majority carrier of the channel region 7 and charges the channel region 7 to a positive bias. The N⁺ layer 3a to which the source line SL is connected is at 0 V, and hence the channel region 7 is charged to the built-in voltage Vb (about 0.7 V) of the PN junction between the N⁺ layer 3a to which the source line SL is connected and the channel region 7. When the channel region 7 is charged to a positive bias, the threshold voltages of the first N channel MOS transistor and the second N channel MOS transistor decrease due to the substrate bias effect. This results in, as illustrated in FIG. 3C, a decrease in the threshold voltage of the N channel MOS transistor of the second channel region 7b to which the word line WL is connected. This write state of the channel region 7 is assigned to logical storage data “1”.

Note that, at the time of the write operation, instead of the first boundary region, at the second boundary region between the first impurity layer and the first channel semiconductor layer or at the third boundary region between the second impurity layer and the second channel semiconductor layer, the impact ionization phenomenon or GIDL current may be caused to generate electron-hole pairs, to cause the generated hole group 11 to charge the channel region 7. Note that the conditions of voltages applied to the bit line BL, the source line SL, the word line WL, and the plate line PL are an example for performing the write operation; other operation conditions for performing the write operation may be employed.

Referring to FIGS. 4AA-4AC and FIGS. 4BD-4BG, the dynamic flash memory cell according to the first embodiment of the present invention will be described in terms of read operation and its related memory cell structure. Referring to FIG. 4AA to FIG. 4AC, the read operation of the dynamic flash memory cell will be described. As illustrated in (a) of the drawing, charging of the channel region 7 to the built-in voltage Vb (about 0.7 V) results in a decrease in the threshold voltage of the N channel MOS transistor due to the substrate bias effect. This state is assigned to logical storage data “1”. As illustrated in FIG. 4AB, when the memory block selected prior to writing is in an erase state “0” in advance, the channel region 7 is at a floating voltage V_{FB} equal to V_{ERA}+Vb. The write operation causes random storage of write state “1”. This results in, for the word line WL, generation of logical storage data of logical “0” and “1”. As illustrated in FIG. 4AC, the difference between the two threshold voltages for the word line WL is used to perform reading using a sense amplifier. In data reading, the voltage applied to the first gate conductor layer 5a connecting to the plate line PL is set to be higher than the threshold voltage at the time of logical storage data “1” and to be lower than the threshold voltage at the time of logical storage data “0”, to thereby provide, as illustrated in FIG. 4AC, a property in which, in reading of logical storage data “0”, in spite of setting the word line WL to a high voltage, no current flows.

Referring to FIG. 4BD to FIG. 4BG, for the dynamic flash memory cell according to the first embodiment of the present invention, at the time of the read operation, the first gate conductor layer 5a and the second gate conductor layer 5b will be described in terms of the magnitude relation of the two gate capacitances and their related operations. The gate capacitance of the second gate conductor layer 5b to which the word line WL connects is desirably designed so as to be lower than the gate capacitance of the first gate conductor layer 5a to which the plate line PL connects. As illustrated in FIG. 4BD, the perpendicular length of the first gate conductor layer 5a to which the plate line PL connects is set to be larger than the perpendicular length of the second gate conductor layer 5b to which the word line WL connects, to make the gate capacitance of the second gate conductor layer 5b to which the word line WL connects be lower than the gate capacitance of the first gate conductor layer 5a to which the plate line PL connects. FIG. 4BE illustrates the equivalent circuit of the single cell of the dynamic flash memory in FIG. 4BD.

FIG. 4BF illustrates the coupling capacitance relation of the dynamic flash memory where C_{WL} is the capacitance of the second gate conductor layer 5b, C_{PL} is the capacitance of the first gate conductor layer 5a, C_{BL} is the capacitance of the PN junction between the N⁺ layer 3b serving as the drain and the second channel region 7b, and C_{SL} is the capacitance of the PN junction between the N⁺ layer 3a serving as the source and the first channel region 7a. As illustrated in FIG. 4BG, when the voltage of the word line WL changes, its operation affects, as noise, the channel region 7. At this time, the potential change ΔV_{FB} of the channel region 7 is expressed as follows.

ΔV_{FB}=C_{WL}/(C_{PL}+C_{WL}+C_{BL}+C_{SL})×V_{ReadWL} (1)

where V_{ReadWL} is the changing potential of the word line WL at the time of reading. As is clear from Formula (1), relative to the total capacitance C_{PL}+C_{WL}+C_{BL}+C_{SL} of the channel region 7, a decrease in the contribution ratio of C_{WL} results in a decrease in ΔV_{FB}. C_{BL}+C_{SL} is the capacitance of the PN junction and can be increased by, for example, increasing the diameter of the Si pillar 2. However, this is not desirable for miniaturization of the memory cell. By contrast, the perpendicular length of the first gate conductor layer 5a to which the plate line PL connects can be made even larger than the perpendicular length of the first gate conductor layer 5b to which the word line WL connects, to thereby achieve, without a decrease in the degree of integration of the memory cell in plan view, a further decrease in ΔV_{FB}. Note that the conditions of voltages applied to the bit line BL, the source line SL, the word line WL, and the plate line PL are an example for performing the read operation; other operation conditions for performing the read operation may be employed.

Referring to FIGS. 5A-5D, the memory cell of the dynamic flash memory according to this embodiment and a Fin transistor used as the driving circuit and the signal processing circuit of the memory cell will be described in terms of structures. FIG. 5A is a sectional view of the dynamic flash memory; FIG. 5B is a sectional view taken along line Y-Y′ in FIG. 5A and in the perpendicular direction in FIG. 5A. FIG. 5C is a sectional view of the Fin transistor; FIG. 5D is a sectional view taken along line Y1-Y1′ in FIG. 5C and in the perpendicular direction in FIG. 5C. The memory cell of the dynamic flash memory and the Fin transistor are disposed on the same P-layer substrate 10. In the actual dynamic flash memory, a large number of memory cells are two-dimensionally formed.

As illustrated in FIG. 5A and FIG. 5B, a P layer 9 (hereafter, semiconductor regions containing an acceptor impurity will be referred to as “P layers”) and an N⁺ layer 13a (serving as an example of “first impurity layer” in CLAIMS) connecting to the P layer 9 constitute a substrate 10 (serving as an example of “substrate” in CLAIMS). To the N⁺ layer 13a, a Si pillar 11A (serving as an example of “first semiconductor pillar” in CLAIMS) connects. In the top portion of the Si pillar 11A, an N⁺ layer 13b (serving as an example of “second impurity layer” in CLAIMS) is disposed. On the N⁺ layer 13a in the outer periphery portion around the Si pillar 11A, a SiO₂ layer 14 is disposed. A HfO₂ layer 15 (serving as an example of “first gate insulating layer” in CLAIMS) is disposed so as to surround the lower side surface of the Si pillar 11A. A TiN layer 16 (serving as an example of “first gate conductor layer” in CLAIMS) is disposed so as to surround the side surface of the HfO₂ layer 15. On the side surface of the Si pillar 11A, the side surface being positioned between the upper end of the HfO₂ layer 15 of the Si pillar 11A and the lower end of the N⁺ layer 13b, and on the upper surface of the TiN layer 16, a HfO₂ layer 18 (serving as an example of “second gate insulating layer” in CLAIMS) is disposed. A TiN layer 19 (serving as an example of “second gate conductor layer” in CLAIMS) is disposed so as to surround the HfO₂ layer. The N⁺ layer 13a connects to the source line SL illustrated in FIG. 1; the N⁺ layer 13b connects to the bit line BL; the TiN layer 16 connects to the plate line PL; the TiN layer 19 connects to the word line WL. The channel layer of the Si pillar 11A disposed between the N⁺ layers 13a and 13b is constituted by a first channel layer 11a surrounded by the HfO₂ layer 15 and a second channel layer 11b surrounded by the HfO₂ layer 18.

As illustrated in FIG. 5C and FIG. 5D, on the substrate 10 constituted by the P layer, a Si pillar 11B (serving as an example of “second semiconductor pillar” in CLAIMS) is disposed. In the lower portion of the Si pillar 11B and on the P-layer substrate 10 in the outer periphery portion around the Si pillar 11B, a SiO₂ layer 20 (serving as an example of “second insulating layer” in CLAIMS) is disposed. At both ends of the upper portion of the Si pillar 11B, an N⁺ layer 13c (serving as an example of “third impurity layer” in CLAIMS) and an N⁺ layer 13d (serving as an example of “fourth impurity layer” in CLAIMS) are disposed. A HfO₂ layer 18b is disposed so as to surround, in the perpendicular direction, above the SiO₂ layer 20, the side surface of the Si pillar 11B. A TiN layer 19b (serving as an example of “third gate conductor layer” in CLAIMS) is disposed so as to surround the HfO₂ layer 18b. The upper portion of the Si pillar 11B between the N⁺ layers 13c and 13d is a channel layer 11d of the Fin transistor. The Si pillar 11B is constituted by the channel layer 11d of the Fin transistor and a Si layer base 11c disposed under the channel layer 11d. Note that, in the outer periphery portion around the bottom portion of the Si layer base 11c, the SiO₂ layer 14 in the dynamic flash memory cell may be disposed. The HfO₂ layer 15 in the dynamic flash memory cell may be formed so as to connect to the side surface of the Si layer base 11c.

The Si pillar 11A of the dynamic flash memory illustrated in FIG. 5A and FIG. 5B and the Si pillar 11B of the Fin transistor illustrated in FIG. 5C and FIG. 5D are both on the substrate 10. The bottom surface positions A of the Si pillar 11A and the Si pillar 11B are the same.

The Si pillar 11A of the dynamic flash memory and the Si pillar 11B of the Fin transistor are each divided, near position B in the perpendicular direction, into two regions. The Si pillar 11A is constituted by the first channel layer 11a surrounded by the HfO₂ layer 15 and the second channel layer 11b surrounded by the HfO₂ layer 18. The Si pillar 11B is constituted by the Si layer base 11c and the channel layer 11d of the Fin transistor. In the upper portion of the Si pillar 11A, the transistor of the dynamic flash memory is disposed; in the upper portion of the Si pillar 11B, the Fin transistor is disposed.

The Si pillar 11A of the dynamic flash memory and the Si pillar 11B of the Fin transistor are the same in terms of height A-C.

Note that, even when the Si pillar 2 in FIG. 1 and the Si pillar 11A in FIGS. 5A-5D have a horizontal sectional shape that is circular, elliptical, or rectangular, the dynamic flash memory operation described in this embodiment can be performed. On the same chip, dynamic flash memory cells having circular, elliptical, and rectangular shapes may together be disposed.

In the description for FIG. 5A and FIG. 5B, it has been stated that the upper surface position of the Si pillar 11A is at the upper surface position of the N⁺ layer 13b; however, when the N⁺ layer 13b is formed after formation of the TiN layer 19, by, for example, an epitaxial crystal growth process, the lower end of the N⁺ layer 13b is at the upper surface of the Si pillar 11A.

For FIG. 1, it has been stated that the first gate conductor layer 5a connects to the plate line PL and the second gate conductor layer 5b connects to the word line WL. Alternatively, even when the first gate conductor layer 5a connects to the word line WL and the second gate conductor layer 5b connects to the plate line PL, normally the dynamic flash memory operation can be performed. In this case, in FIGS. 5A-5D, the first gate conductor layer 16 connects to the word line, and hence, in plan view, the gate conductor layers at the positions of the first gate conductor layers of adjacent memory cells disposed in a direction perpendicular to the bit line BL are formed so as to connect to the word line. For FIG. 1, it has been stated that the N⁺ layer 3a connects to the source line SL and the N⁺ layer 3b connects to the bit line BL; alternatively, even when the N⁺ layer 3a is connected to the bit line BL and the N⁺ layer 3b is connected to the source line SL, normally the dynamic flash memory operation can be performed.

In FIG. 1, one or both of the first gate conductor layer 5a and the second gate conductor layer 5b may be divided, in plan view, into two or more portions, and the portions may be operated as the conductive electrodes of the plate line and the word line synchronously or asynchronously. This also achieves the dynamic flash memory operation.

In FIG. 1, in the perpendicular direction, one or both of the first gate conductor layer 5a and the second gate conductor layer 5b may be divided in the perpendicular direction. These can be operated synchronously or asynchronously. This also achieves the dynamic flash memory operation.

This embodiment provides the following features.

### (Feature 1)

For the plate line PL of the dynamic flash memory cell according to the first embodiment of the present invention, when the dynamic flash memory cell performs the write or read operation, the voltage of the word line WL changes up and down. At this time, the plate line PL plays the role of reducing the capacitive coupling ratio between the word line WL and the channel region 7. As a result, during up-and-down changes in the voltage of the word line WL, the effect due to the changes in the voltage in the channel region 7 can be considerably suppressed. As a result, the difference between the threshold voltages of the SGT transistor for the word line WL indicating logical “0” and “1” can be made to be large. This leads to an increase in the operation margin of the dynamic flash memory cell. In data reading, the voltage applied to the first gate conductor layer 5a connecting to the plate line PL can be set to be higher than the threshold voltage at the time of logical storage data “1”, and to be lower than the threshold voltage at the time of logical storage data “0”, to thereby provide a property in which, in reading of logical storage data “0”, in spite of setting the word line WL to a high voltage, no current flows. This leads to a further increase in the operation margin of the dynamic flash memory cell.

### (Feature 2)

As illustrated in FIGS. 5A-5D, the Si pillar 11A of the dynamic flash memory cell and the Si pillar 11B of the Fin transistor have bottom portions at the same position A and are formed so as to have the same height (A-C) on the substrate 10. For, on the substrate 10, the top portion of the first channel layer 11a of the dynamic flash memory and the top portion of the Si layer base 11c of the Fin transistor are formed so as to have upper surfaces at substantially the same position, so that the TiN layer 19 serving as the word line WL of the dynamic flash memory cell and the TiN layer 23 serving as the gate of the Fin transistor are positioned substantially at the same height in the perpendicular direction. Thus, the transistor connecting to the word line WL of the dynamic flash memory and the Fin transistor are formed substantially at the same height. This facilitates formation of the dynamic flash memory cell and the Fin transistor circuit on the substrate 10. This leads to a reduction in the production costs for the dynamic-flash-memory-including semiconductor device.

### Second Embodiment

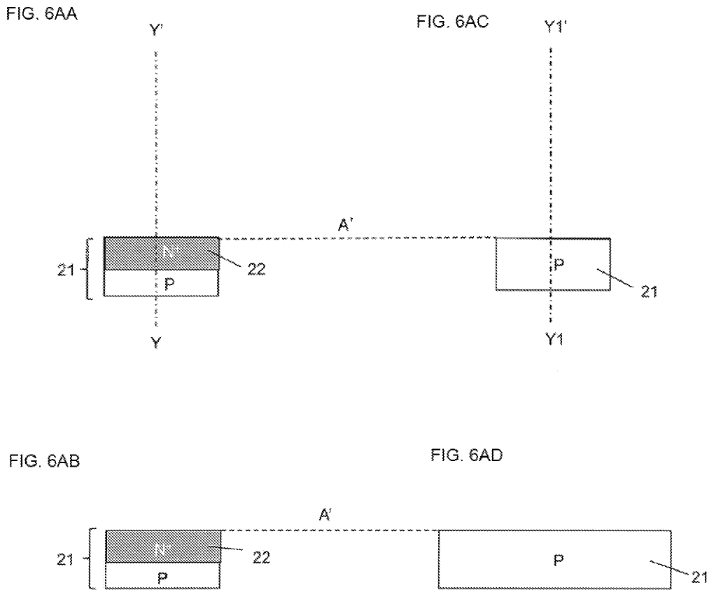

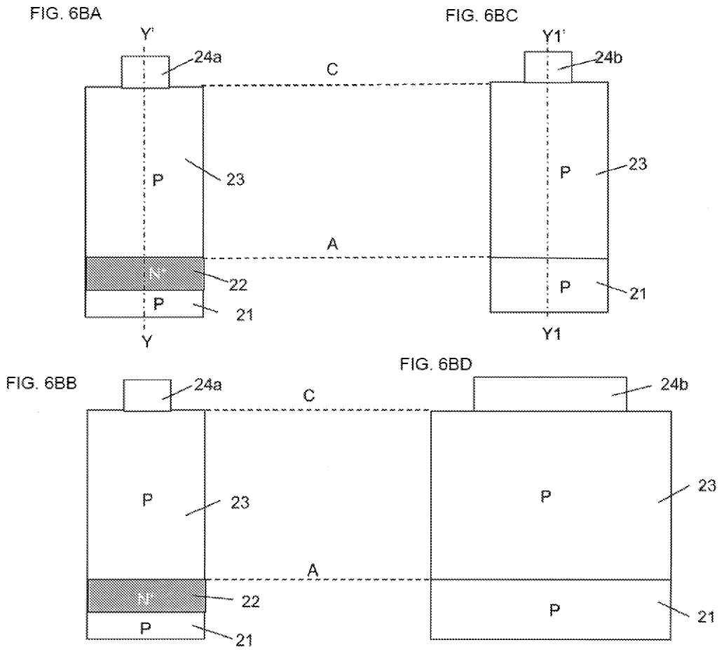

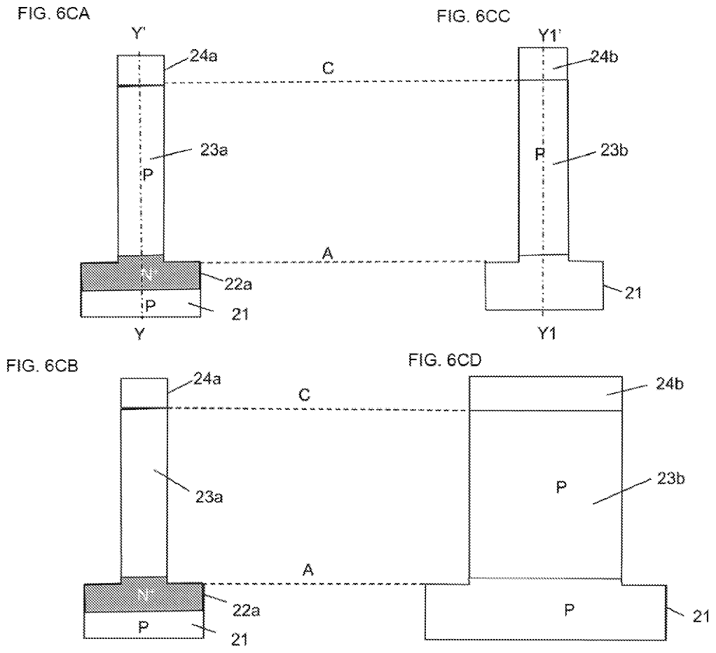

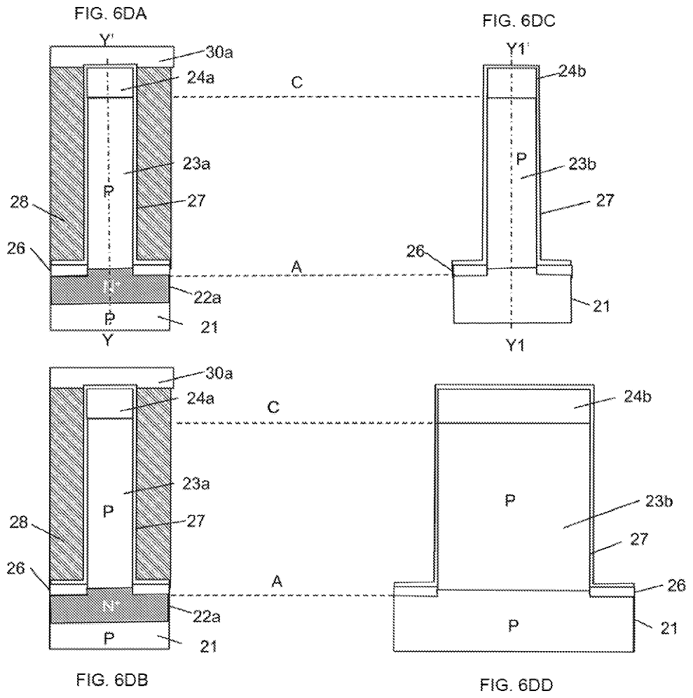

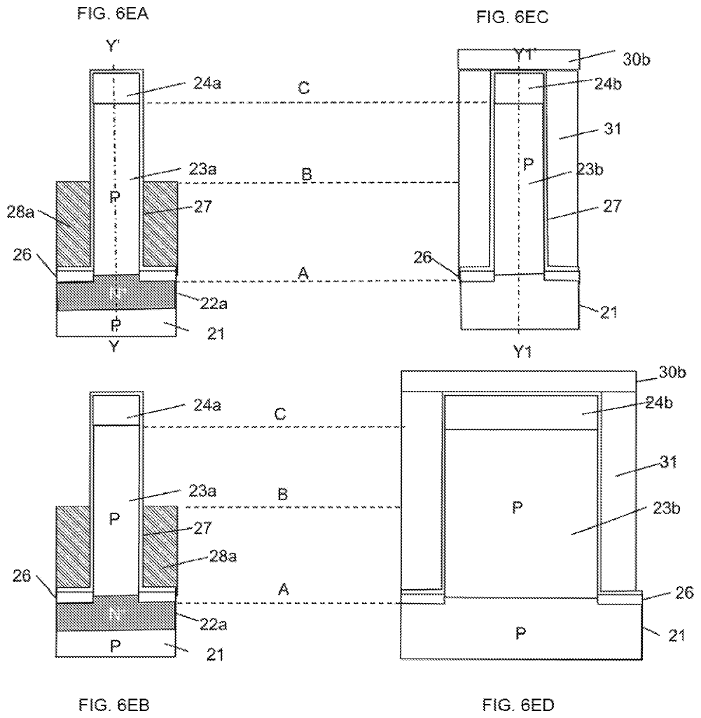

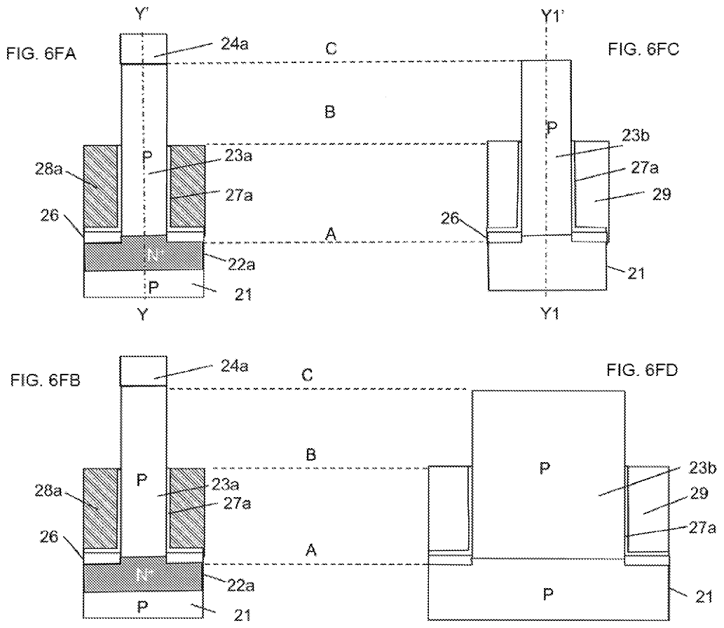

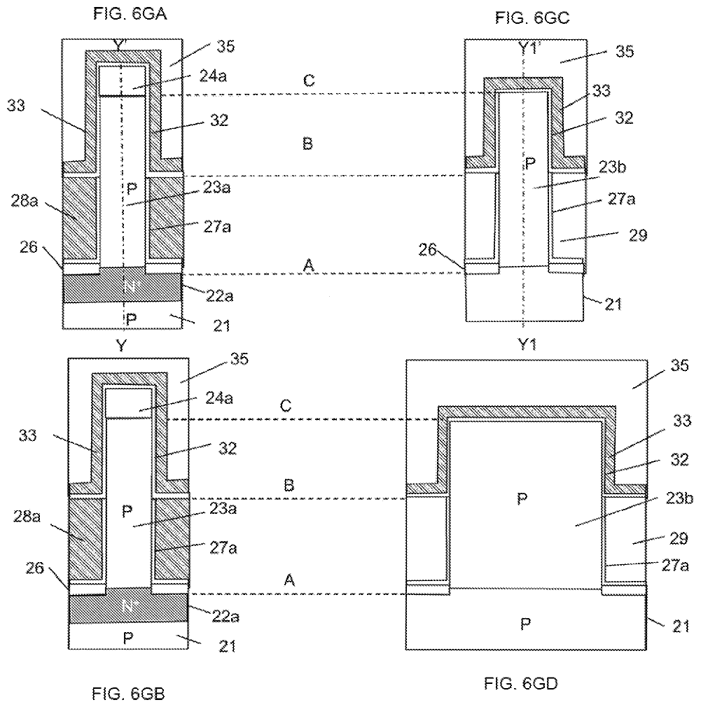

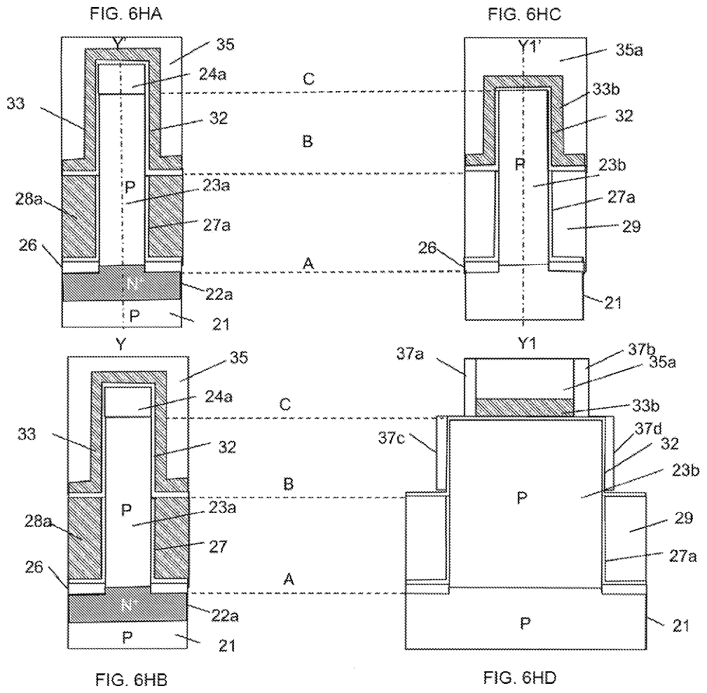

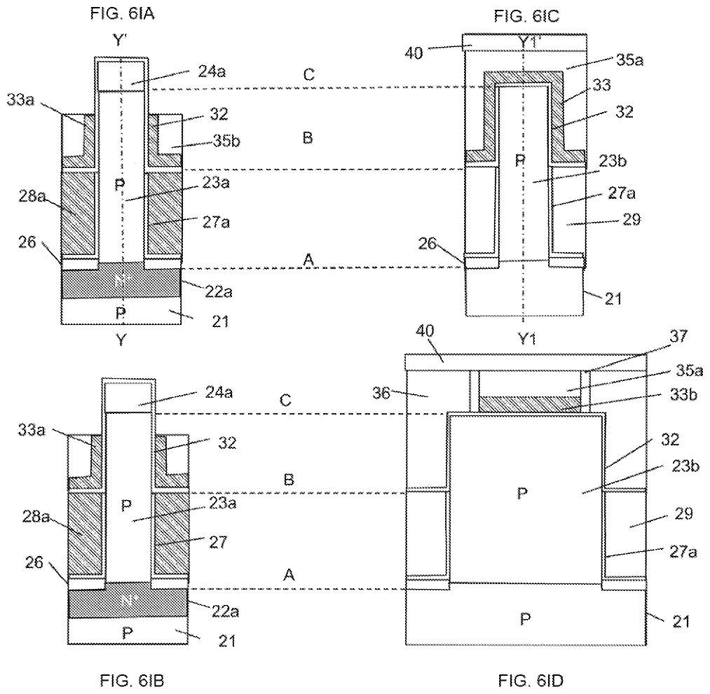

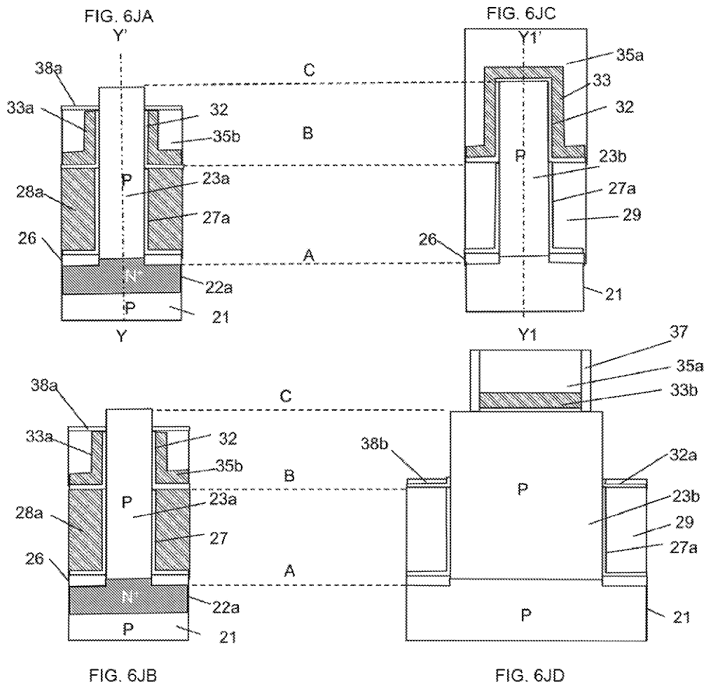

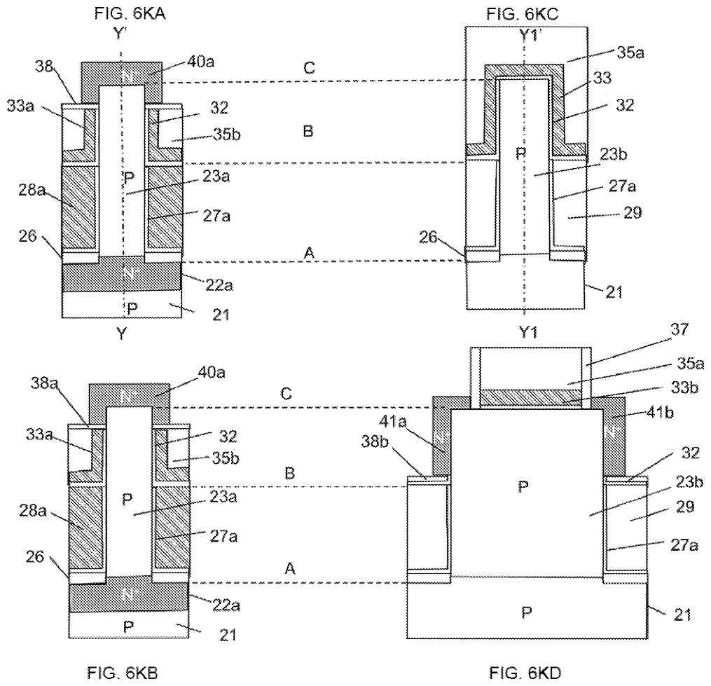

Referring to FIG. 6AA to FIG. 6JD, a production method in which a dynamic flash memory cell and a Fin transistor are formed on the same substrate 21 according to a second embodiment of the present invention will be described. In each of the drawings, (a) is a sectional view of the dynamic flash memory cell; (b) is a sectional view taken along line Y-Y′ in (a) and in the perpendicular direction in (a); (c) is a sectional view of the Fin transistor; and (d) is a sectional view taken along line Y1-Y1′ in (c) and in the perpendicular direction in (c).

As illustrated in FIGS. 6AA-6AD, into the upper layer of the P-layer substrate 21 in the dynamic flash memory cell region, a phosphorus (P) impurity is applied by an ion implantation process to form an N⁺ layer 22. Note that, for the N⁺ layer 22, for example, the surface layer of the P-layer substrate 21 in the dynamic flash memory cell region may be etched and subjected to an epitaxial crystal growth process to form the N⁺ layer 22. In this step, initially, a region of the P-layer substrate 21, the region being outside of the dynamic flash memory cell region, is covered with a SiO₂ layer. Subsequently, through the SiO₂ layer serving as a mask, the surface layer of the P-layer substrate 21 is etched. Subsequently, an epitaxial crystal growth process is performed to form an N⁺ layer over the whole structure. Subsequently, a CMP (Chemical Mechanical Polishing) process is performed to perform polishing until the surface position is lowered to the P-layer substrate 21. In this way, the N⁺ layer 22 is embedded within the P-layer substrate 21. In this case, the surface of the dynamic flash memory cell region N⁺ layer 22 is positioned at the same position A′ as with the surface of the P-layer substrate 21 in the Fin transistor region.

Subsequently, as illustrated in FIGS. 6BA-6BD, over the entirety of the dynamic flash memory cell region and the Fin transistor region, an epitaxial crystal growth process is performed to form a P layer 23. Subsequently, on the P layer 23 in the dynamic flash memory cell region, a first mask material layer 24a is formed and, on the P layer 23 in the Fin transistor region, a second mask material layer 24b is formed.

Subsequently, as illustrated in FIG. 6C, through the first mask material layer 24a and the second mask material layer 24b serving as masks, the P layer 23 is etched until the bottom portion is positioned near the position of the upper surface of the N⁺ layer 22a, to form Si pillars 23a and 23b.

Subsequently, as illustrated in FIGS. 6DA-6DD, in the outer periphery portions around the Si pillars 23a and 23b, on the N⁺ layer 22a in the dynamic flash memory cell region and on the P-layer substrate 21 in the Fin transistor region, a SiO₂ layer 26 is formed. Subsequently, over the whole structure, a HfO₂ layer 27 is formed. Subsequently, over the whole structure, a TiN layer (not shown) is deposited. Subsequently, a CMP process is performed to perform polishing until the upper surface position is lowered to the upper surface positions of the mask material layers 24a and 24b. Subsequently, a mask material layer 30a is formed so as to cover the dynamic flash memory cell region. Subsequently, through the mask material layer 30a serving as a mask, the TiN layer in the Fin transistor region is removed. This forms a TiN layer 28 surrounding the HfO₂ layer 27 in the dynamic flash memory cell region. Note that, during removal of the TiN layer in the Fin transistor region, the SiO₂ layer 26 and the HfO₂ layer 27 in the Fin transistor region may be removed.

Subsequently, the whole structure is covered with a SiO₂ layer (not shown). Subsequently, as illustrated in FIGS. 6EA-6ED, a CMP process is performed to polish the whole structure until the upper surface position is lowered to the upper surface positions of the mask material layers 24a and 24b, to form a SiO₂ layer 31 in the Fin transistor region. Subsequently, a mask material layer 30b is formed so as to cover the Fin transistor region. Subsequently, an RIE process is performed to etch the TiN layer 28 until its upper surface is lowered to Position B to form a TiN layer 28a.

Subsequently, as illustrated in FIGS. 6FA-6FD, the HfO₂ layer 27 covering portions of the Si pillars 23a and 23b above Position B and the mask material layers 24a and 24b is removed, to form a HfO₂ layer 27a surrounding portions of the Si pillars 23a and 23b below Position B. Subsequently, the mask material layer 24b on the Si pillar 23b is removed.

Subsequently, as illustrated in FIGS. 6GA-6GD, the whole structure is then covered with a HfO₂ layer 32. Subsequently, the whole structure is covered with a TiN layer 33. Subsequently, over the whole structure, a SiO₂ layer 35 is formed.

Subsequently, as illustrated in FIGS. 6HA-6HD, the lithography technology and RIE process are used to etch the SiO₂ layer 35, to form a SiO₂ layer 35a surrounding the TiN layer 33 in the Fin transistor region. Subsequently, through the SiO₂ layer 35a serving as a mask, the TiN layer 33 is etched to form a TiN layer 33b. Subsequently, the whole structure is covered with an insulating layer (not shown). Subsequently, an RIE process is used to etch the insulating layer, to form, on the side surfaces of the TiN layer 33b and the SiO₂ layer 35a, spacer layers 37a and 37b and, on the upper side surfaces of the Si pillar 23b, spacer layers 37c and 37d.

Subsequently, the whole structure is covered with a SiO₂ layer (not shown). Subsequently, as illustrated in FIGS. 6IA-6ID, a CMP process is used to perform polishing until the upper surface position is lowered to the upper surface position of the mask material layer 24a to form a SiO₂ layer 36. Subsequently, a mask material layer 40 is formed so as to cover the Fin transistor region. Subsequently, an RIE process is used to etch the TiN layer 33 and the SiO₂ layer 35, to form, in the dynamic flash memory cell region, a TiN layer 33a and a SiO₂ layer 35b.

Subsequently, as illustrated in FIGS. 6JA-6JD, the mask material layer 40, the SiO₂ layer 36, and the spacer layers 37c and 37d are removed. Subsequently, in the outer periphery portions around the Si pillars 23a and 23b, insulating layers 38a and 38b are formed. Subsequently, in the upper portions of the Si pillars 23a and 23b, the HfO₂ layer 32 exposed is removed. Subsequently, the mask material layer 24a is removed.

Subsequently, as illustrated in FIGS. 6KA-6KD, a selective epitaxial crystal growth process is performed to form N⁺ layers 40a, 41a, and 41b so as to surround the exposed top portion of the Si pillar 23a. Subsequently, a source line SL is connected to the N⁺ layer 22a, a plate line PL is connected to the TiN layer 28a, a word line WL is connected to the TiN layer 33a, and a bit line BL is connected to the N⁺ layer 40a, to thereby form a dynamic flash memory cell. Subsequently, a gate line is connected to the TiN layer 33b and one of the N⁺ layers 41a and 41b is connected to the source line, to form a Fin transistor in which the other is connected to the drain line.

Note that, in the second embodiment, the example in which the dynamic flash memory cell and the N channel Fin transistor are formed on the P-layer substrate 21 has been described. Ordinarily, in a circuit using a Fin transistor, a CMOS circuit is used and hence, on the P-layer substrate 21, a P channel Fin transistor is similarly formed.

In this embodiment, the gate insulating layers of the dynamic flash memory cell and the Fin transistor are formed as the same HfO₂ layer 32; alternatively, the gate insulating layers of the dynamic flash memory cell and the Fin transistor may be individually formed as layers different in material. The same applies to, in the dynamic flash memory cell, the gate conductor layer that is the TiN layer 33.

As illustrated in FIGS. 6KA-6KD, when the N⁺ layers 40a, 41a, and 41b are simultaneously formed, the N⁺ layers 40a, 41a, and 41b are formed of the same semiconductor base material, and contain the same donor impurity atoms. Alternatively, the N⁺ layer 40a may be formed so as to be different from the N⁺ layers 41a and 41b in terms of semiconductor base material. The N⁺ layer 40a may be formed so as to contain donor impurity atoms different from those contained in the N⁺ layers 41a and 41b.

This embodiment provides the following features.

### (Feature 1)

The Si pillar 23a of the dynamic flash memory cell and the Si pillar 23b of the Fin transistor are simultaneously formed, to thereby simplify the production steps.

### (Feature 2)

The TiN layer 33 serving as the gate TiN layer 33a of the dynamic flash memory cell and the TiN layer 33 serving as the gate TiN layer 33b of the Fin transistor are simultaneously formed, to thereby simplify the production steps.

### (Feature 3)

The N⁺ layer 40a connecting to the bit line BL in the dynamic flash memory cell and the N⁺ layers 41a and 41b serving as the source and the drain in the Fin transistor are simultaneously formed, to thereby simplify the production steps.

### (Feature 4)

The word line transistor of the dynamic flash memory cell and the Fin transistor are formed, in the perpendicular direction, at the same height, to thereby facilitate the production.

### Other Embodiments

Note that, in the present invention, the Si pillars 2, 11A, 11B, 23a, and 23b are formed; alternatively, other semiconductor materials may be used to form semiconductor pillars.

In the embodiments, the N⁺ layers 3a, 3b, 13a, 13b, 13c, and 13d may alternatively be formed as layers of Si containing a donor impurity or another semiconductor material, or may be formed as layers different in semiconductor material. As the process of forming these, an epitaxial crystal growth process or another process may be performed to form the N⁺ layers.

In the first embodiment, as the gate conductor layer 5a connecting to the plate line PL, the TiN layer 16 is used. Alternatively, instead of the TiN layer 16, a single conductor material layer or plural conductor material layers in combination may be used. Similarly, as the word line WL and the gate conductor layer 5b connecting to the word line WL, the TiN layer 19 is used. Alternatively, instead of the TiN layers 16 and 19, a single conductor material layer or plural conductor material layers in combination may be used. The gate TiN layers 16 and 19 may, in their outer portions, connect to, for example, a wiring metal layer formed of W. The same applies to other embodiments according to the present invention.

In the first embodiment, the Si pillars 2 and 11A have a plan-view shape that is circular. Alternatively, the Si pillars 2 and 11A may have a plan-view shape that is circular, elliptical, or elongated in one direction, for example. Also in the logic circuit region formed apart from the dynamic flash memory cell region, depending on the logic circuit design, in the logic circuit region, Si pillars different in plan-view shapes can be formed in combination to form an SGT and a Fin transistor. In the logic circuit, a CMOS circuit using N channel and P channel Fin transistors is formed. The same applies to other embodiments according to the present invention.

FIGS. 5A-5D has been described using the Si pillars 11A and 11B having rectangular sections; alternatively, they may be trapezoidal. In the Si pillar 11A in the dynamic flash memory cell, the section of the Si pillar 11A surrounded by the HfO₂ layer 15 and the section of the Si pillar 11A surrounded by the HfO₂ layer 18 may be different and respectively rectangular and trapezoidal. The same applies to other embodiments according to the present invention.

As with the substrate 1, the substrates 10 and 21 may be formed as SOI (Silicon On Insulator) or monolayers or multilayers that are layers of Si or other semiconductor materials or conductor layers. The substrates 10 and 21 may be well layers constituted by monolayers or multilayers of N layers or P layers.

In the first embodiment, the HfO₂ layers 15, 18, and 22 having been described may alternatively be, as long as they function as gate insulating layers, other insulating layers that are monolayers or multilayers. The TiN layers 16, 19, and 23 may alternatively be, as long as they have the function of gate conductor layers, other conductor layers that are monolayers or multilayers. The HfO₂ layers 15, 18, and 22 may alternatively be formed as material layers different in materials and physical values such as thickness. The same applies to other embodiments according to the present invention.

In the second embodiment, a conductor layer such as a W layer may be used so as to connect to the N⁺ layer 22a of the bottom portion of the Si pillar 23a. The same applies to other embodiments according to the present invention. The N⁺ layer 22a may be connected to the N⁺ layer in the bottom portion of the Si pillar in the memory cell adjacent to the Si pillar 23a. The N⁺ layer 22a may be electrically isolated, using, for example, STI (Shallow Trench Isolation) or a well structure, from the N⁺ layer of the memory cell adjacent to the Si pillar 23a. In this case, for each of the isolated N⁺ layers, a low-resistance conductor layer needs to be formed in contact with the N⁺ layer. This enables independent driving of the isolated N⁺ layers connecting to source lines. The same applies to other embodiments according to the present invention.

In the second embodiment, the N⁺ layers 22a, 40a, 41a, and 41b may alternatively be formed as layers of Si containing a donor impurity or another semiconductor material. As the process of forming these, an epitaxial crystal growth process or another process may be performed to form the N⁺ layers. The same applies to other embodiments according to the present invention.

In the first embodiment, as the plate line PL and the gate conductor layer 5a connecting to the plate line PL, the TiN layer 16 is used. Alternatively, instead of the TiN layer 16, a single conductor material layer or plural conductor material layers in combination may be used. Similarly, as the gate conductor layer 5b connecting to the word line WL, the TiN layer 19 is used. Alternatively, instead of the TiN layer 19, a single conductor material layer or plural conductor material layers in combination may be used. The gate TiN layers 16 and 19 may connect, in their outer portions, to a wiring metal layer formed of TaN or W, for example. The same applies to other embodiments according to the present invention.

In FIG. 1, the gate length of the first gate conductor layer 5a can be made to be larger than the gate length of the second gate conductor layer 5b such that the gate capacitance of the first gate conductor layer 5a connected to the plate line PL becomes higher than the gate capacitance of the second gate conductor layer 5b connected to the word line WL, to thereby make the gate capacitance of the first gate conductor layer 5a be even higher than the gate capacitance of the second gate conductor layer 5b. Also, in a structure in which the gate length of the first gate conductor layer 5a is or is not made to be larger than the gate length of the second gate conductor layer 5b, the layer thicknesses of the gate insulating layers can be changed such that the film thickness of the gate insulating film of the first gate insulating layer 4a is made to be smaller than the film thickness of the gate insulating film of the second gate insulating layer 4b, to make the gate capacitance of the first gate conductor layer 5a be even higher than the gate capacitance of the second gate conductor layer 5b. The dielectric constants of the materials for the gate insulating layers may be changed such that the dielectric constant of the gate insulating film of the first gate insulating layer 4a is made to be higher than the dielectric constant of the gate insulating film of the second gate insulating layer 4b. A combination of some of the lengths of the gate conductor layers 5a and 5b and the layer thicknesses and the dielectric constants of the gate insulating layers 4a and 4b may be selected such that the gate capacitance of the first gate conductor layer 5a is made to be even higher than the gate capacitance of the second gate conductor layer 5b. The same applies to other embodiments according to the present invention.

Note that, in FIGS. 5A-5D, between the Si pillar 11A and the N⁺ layers 13a and 13b, an intermediate region such as an LDD (Lightly Doped Drain) may be disposed. Similarly, between the channel layer 11d and the N⁺ layers 13c and 13d, an intermediate region such as an LDD may be disposed. The same applies to other embodiments according to the present invention.

In FIGS. 6EA-6ED, after formation of the TiN layer 28a, lithography and RIE etching steps may be performed to divide the TiN layer 28a surrounding the HfO₂ layer 27, into two regions.

For the present invention, without departing from the broad spirit and scope of the present invention, various embodiments and modifications can be made. The above-described embodiments are provided for the purpose of describing examples of the present invention and do not limit the scope of the present invention. The examples and modifications can be appropriately combined. In addition, the embodiments from which a portion of the features has been removed as needed also fall in the scope of the technical idea of the present invention.

### INDUSTRIAL APPLICABILITY

Memory-element-including semiconductor devices according to the present invention provide high-density high-performance dynamic-flash-memory-including semiconductor devices.

1. A memory-element-including semiconductor device comprising a dynamic flash memory cell and a Fin transistor,
wherein the dynamic flash memory cell includes
a first semiconductor pillar disposed on a substrate so as to stand in a direction perpendicular to the substrate,
a first impurity layer connecting to a bottom portion of the first semiconductor pillar,
a second impurity layer disposed in a top portion of the first semiconductor pillar or disposed so as to connect to the top portion,
a first gate insulating layer surrounding a lower portion of the first semiconductor pillar and being in contact with the first impurity layer,
a second gate insulating layer being in contact with the first gate insulating layer and surrounding an upper portion of the first semiconductor pillar,
a first gate conductor layer surrounding a portion or entirety of the first gate insulating layer,
a second gate conductor layer surrounding the second gate insulating layer, and
a first insulating layer disposed between the first gate conductor layer and the second gate conductor layer,
the dynamic flash memory cell is configured to perform a memory write operation of controlling voltages applied to the first impurity layer, the second impurity layer, the first gate conductor layer, and the second gate conductor layer to perform an operation of causing, within the first semiconductor pillar, an impact ionization phenomenon due to a current flowing between the first impurity layer and the second impurity layer or a gate induced drain leakage current to generate an electron group and a hole group, an operation of discharging, of the generated electron group and hole group, the electron group from the first impurity layer or the second impurity layer, and causing a portion or entirety of the hole group to remain within the first semiconductor pillar, and a memory erase operation of removing, from one or both of the first impurity layer and the second impurity layer, the remaining hole group of the hole group,
the Fin transistor includes
a second semiconductor pillar disposed on the substrate so as to stand in a direction perpendicular to the substrate,
a second insulating layer surrounding a lower portion of the second semiconductor pillar,
a third impurity layer and a fourth impurity layer individually connecting to, above the second insulating layer, both side surfaces, in a longitudinal direction, of an upper portion of the second semiconductor pillar,
a third gate insulating layer surrounding the third impurity layer, the fourth impurity layer, and the second semiconductor pillar therebetween, and
a third gate conductor layer surrounding the third gate insulating layer, and
bottom portions of the first semiconductor pillar and the second semiconductor pillar are disposed at substantially the same position in the perpendicular direction.

2. The memory-element-including semiconductor device according to claim 1, wherein, in the perpendicular direction, a lower end of the second gate conductor layer and a lower end of the third gate conductor layer are substantially at the same position.

3. The memory-element-including semiconductor device according to claim 1, wherein top portions of the first semiconductor pillar and the second semiconductor pillar are substantially at the same position in the perpendicular direction.

4. The memory-element-including semiconductor device according to claim 1, wherein the second impurity layer, the third impurity layer, and the fourth impurity layer contain the same donor impurity atoms and are formed of the same semiconductor base material.

5. The memory-element-including semiconductor device according to claim 1, wherein a wiring line connecting to the first impurity layer is a source line, a wiring line connecting to the second impurity layer is a bit line, a wiring line connected to one of the first gate conductor layer and the second gate conductor layer is a first driving control line, a wiring line connected to another of the first gate conductor layer and the second gate conductor layer is a word line, and
voltages are applied to the source line, the bit line, the first driving control line, and the word line, to perform the memory erase operation and the memory write operation.

6. The memory-element-including semiconductor device according to claim 1, wherein a first gate capacitance between the first gate conductor layer and the first semiconductor pillar is higher than a second gate capacitance between the second gate conductor layer and the first semiconductor pillar.

7. The memory-element-including semiconductor device according to claim 1, wherein the first gate conductor layer is, in plan view, divided into two conductor layers so as to surround the first gate insulating layer.
